(19) United States
(12) Patent Application Publication
(10) Pub. No.: US 2012/0181474 A1
(43) Pub. Date: Jul. 19, 2012

(54) CERAMIC MATERIAL AND PROCESS FOR PRODUCING THE CERAMIC MATERIAL

(75) Inventors: Hermann Gruenbichler, St. Josef (AT); Christl Lisa Mead, St. Martin I.S. (AT); Manfred Schweinzger, Schwanberg (AT); Aniko Nagy, Deutschlandsberg (AT)

(73) Assignee: EPCOS AG, Munich (DE)

(21) Appl. No.: 13/329,826

(22) Filed: Dec. 19, 2011

Related U.S. Application Data
(63) Continuation of application No. PCT/EP2010/058940, filed on Jun. 23, 2010.

(30) Foreign Application Priority Data
Jun. 26, 2009 (DE) 102009030710.9

(51) Int. Cl. H01L 41/187; B28B 11/24; B28B 1/00

(52) U.S. Cl. 252/62.9 PZ; 264/678

(57) ABSTRACT

A material includes a ceramic material having a general formula of

Pb_{1-(m/2)x-z+z}M^{m}ₓ (Zr_{1-y}Ti_{y-z+z})O₃+a-zPbTiO₃,

where M is at least one element selected from: Nd, La, Ba, Sr, Sb, Bi, K, Na; where: 0≦x≦0.1, 0.3≦y≦0.7; 0≦z≦y, 0≦(a-z) ≦0.03; and where m corresponds to a valency of a metal M, and has a value +1, +2 or +3.

### CROSS-REFERENCE TO RELATED APPLICATIONS

This patent application is a continuation of PCT Application No. PCT/EP2010/058940 filed on Jun. 23, 2010, which claims priority to German Patent Application No. 102009030710.9 filed on Jun. 26, 2009. This patent application hereby claims priority to both PCT Application No. PCT/EP2010/058940 and to German Patent Application No. 102009030710.9. PCT Application No. PCT/EP2010/058940 and German Patent Application No. 102009030710.9 are hereby incorporated by reference into this patent application as if set forth herein in full.

### TECHNICAL FIELD

This disclosure relates to a ceramic material.

### BACKGROUND

A widespread problem in the production of piezoelectric ceramic materials is that of producing the material in such a way as to obtain desired piezoelectric parameters, which differ according to requirements.

These piezoelectric parameters are closely linked to the grain growth of the ceramic material during the sintering process. To date, attempts have been made to promote the grain growth in two different ways.

The first way is by sintering at very high temperatures, but this has the disadvantage that if the ceramic material is sintered together with inner electrodes, for example, these have to be produced from a material which melts only at very high temperatures. These materials are precious metals, for example, which are very expensive. A further disadvantage of this variant is that the high temperature results in considerable PbO losses in the ceramic material, as a result of which the composition of the ceramic material changes in a manner which is difficult to control.

The second way was by adding sintering aids such as, for example, silicates or borates to the ceramic material. This procedure has the disadvantage that the sintering aids were incorporated in the ceramic material. Although the grain growth was thus promoted per se, the incorporation of the disruptive foreign substances meant that in turn a deterioration in the piezoelectric parameters would have to be accepted. A further disadvantage is the undesired reaction between the sintering aid and the electrode material, if the ceramic material is sintered together with the inner electrodes.

### SUMMARY

Described herein is a ceramic material which has improved piezoelectric properties.

By way of example, the piezoelectric properties may be the dielectric constant εᵣ, the piezoelectric charge constant d₃₃ or the coupling factor k. The relative dielectric constant Sᵣ is the ratio between the absolute permittivity of the ceramic material and the permittivity in a vacuum, where the absolute permittivity represents a measure of the polarizability in an electric field. The efficacy of the piezo effect is characterized by the piezoelectric charge constant dᵢⱼ, which represents the ratio of the generated charge density to the mechanical deformation. The direction dependency of the parameter is specified by the corresponding indices. The index i of the piezoelectric charge constants indicates the direction of the electric field, and the index j indicates the direction of the deformation by which the crystal reacts to the field. Here, a 1 stands for the x direction, a 2 stands for the y direction and a 3 stands for the z direction. The piezoelectric charge constant d₃₃ therefore denotes the longitudinal extension behavior in the direction of the z axis. The coupling factor k is a measure of the degree of the piezoelectric effect. It describes the ability of a piezoelectric material to convert absorbed electrical energy into mechanical energy, and vice versa. Here, k₃₃ stands for the coupling factor of the longitudinal oscillation. For the longitudinal effect, the polar axis of the crystal is collinear with the deformation direction.

In one embodiment, the ceramic material can be described by the following general formula:

Pb_{1(m/2)x-z+z}M^{m}ₓ (Zr_{1-y}Ti_{y-z+z})O₃+a-zPbTiO₃,

where M is at least one element selected from: Nd, La, Ba, Sr, Sb, Bi, K, Na, and where: 0≦x ≦0.1; 0.3≦y≦0.7; 0≦z≦y; 0≦(a-z) ≦0.03, and where m, corresponds to the valency of the respective metal M, has the value +1, +2 or +3.

According to the dependency on the parameters a and z, the ceramic material is a single-phase or two-phase system. The one phase or both of the phases are present in each case in a perovskite structure, both in the single-phase system and in the two-phase system. The perovskite lattice can be described by the general formula ABO₃. Here, the Pb ions, and if present also the M ions, are arranged at the A sites of the lattice. The Zr ions and also the Ti ions occupy the B sites of the ion lattice.

In this case, m assumes a value of +3 for the elements Nd, La, Sb and Bi, the value +2 for the elements Ba and Sr and the value +1 for the two elements K and Na.

A ceramic material of this composition having parameters which lie in the limits indicated above has very good piezoelectric properties.

It could be possible for d₃₃ values of 400 to 600 pm/V to be achieved.

The good piezoelectric properties can be achieved in this respect without the inclusion of foreign ions, or without it having been necessary to heat the ceramic material to very high temperatures.

In a further embodiment, M is Nd.

Particularly good piezoelectric properties could be achieved for the thus selected M.

In a further embodiment, M is La.

Particularly good piezoelectric properties could likewise be achieved for the thus selected M.

In a further embodiment, the parameter a is greater than the parameter z. In this case, a two-phase system is present.

In a further embodiment of the ceramic material, the parameter a corresponds to the parameter z, i.e. a=z. This gives the formula: Pb_{1-(m/2)x-z+z}M^{m}ₓ (Zr_{1-y}Ti_{y-z+z})O₃.

In this embodiment, a single-phase system having particularly good piezoelectric properties is present.

In a further embodiment, the following holds true for the parameter x: 0.02≦x≦0.03.

For the M content in the given range, particularly good piezoelectric properties could be achieved.

It could be possible for d₃₃ values of 600 to 800 pm/V to be achieved.

In a further embodiment, the following holds true for the parameter z: 0.01≦z≦0.1.

Particularly good piezoelectric properties could be achieved for the thus selected parameter z.

In a further embodiment, the following holds true for the parameters z and a: 0≦(a-z) <0.01.

Particularly good piezoelectric properties could be achieved for the thus selected parameters a and z.

In a further embodiment, the following holds true for the parameters z and a: 0<(a-z)<0.01.

In a further embodiment of the ceramic material, the latter has a mean grain size in the range of 1 μm to 3 μm.

In this respect, the grain size can be determined from a microsection on the basis of microscopic images, such as for example a scanning electron microscope.

Tests have shown that the physical parameter of the mean grain size has a strong influence on the piezoelectric properties of the ceramic material. It is therefore desirable to obtain a ceramic material having a mean grain size which lies in the desired range.

In a further embodiment of the ceramic material, the latter has a density in the range of 7.6 to 8.1 g/cm³.

For a ceramic material having this density, good piezoelectric properties could be achieved.

In this respect, a range of 7.8 to 7.9 g/cm³ is preferred. Particularly good piezoelectric properties could be achieved for this subrange.

In a further exemplary embodiment of the ceramic material, the latter comprises no additional sintering aids.

“No additional sintering aids” is to be understood to mean that, apart from the PbTiO₃ content, which is denoted by a-zPbTiO₃, the ceramic material comprises no further sintering aids. The ceramic material is therefore free of disruptive foreign ions, which would either be incorporated in the crystal lattice or would be present as further phases in the ceramic material. Such foreign ions would have a negative effect on the piezoelectric properties of the ceramic material. The addition of PbTiO₃, which can also be incorporated in the PZT lattice, has a positive influence on the sintering process, for example the grain growth, without the addition of ions which are not already inherently present in ceramic material.

A ceramic material as described above can be used, for example, for multilayered components, such as a piezoelectric actuator.

In addition to the ceramic material itself, this disclosure also describes a process for producing the ceramic material.

In a variant of the process for producing a ceramic material, the process comprises the following process operations: providing the starting substances comprising Pb to a stoichiometric proportion of 1-x-z, M to a stoichiometric proportion of x, Zr to a stoichiometric proportion of 1-y and Ti to a stoichiometric proportion of y-z as process step A), mixing and pre-milling the starting substances as process step B), calcining the mixture from B) as process step C), adding PbTiO₃ to a stoichiometric proportion of a as process step D), mixing and subsequently milling the mixture from D) as process step E), and sintering the mixture from E) to give a ceramic material of the general formula:

Pb_{1-(m/2)x-z+z}M^{m}ₓ (Zr_{1-y}Ti_{y-z+z})O₃+a-zPbTiO₃,

where M is an element selected from: Nd, La, Ba, Sr, Sb, Bi, K, Na; where: 0≦x≦0.1; 0.3≦y≦0.7; 0≦z≦y; 0≦(a-z) ≦0.03; and where m corresponds to the valency of the respective metal M, and has the value +1, +2 or +3, as process step F).

In this context, in process step A) the two elements Pb and Ti are provided in a targeted manner in a stoichiometric quantity which lies, by the proportion z, under the quantity in which these two elements should be present in the finished ceramic material. By contrast, the other two elements M and Zr are introduced in that stoichiometric quantity in which they should then also be present in the finished ceramic material.

In the subsequent process step, step B), the starting substances are mixed and pre-milled. The milling can be effected, for example, using a stirred ball mill comprising zirconium oxide milling balls. The pre-milling can be effected to a particle size of 1 μm, for example.

The pre-milled starting substances are calcined in the subsequent process step, step C).

Only after the calcining, is PbTiO₃ then added to a stoichiometric proportion of a in process step D). In this case, the parameter a is at least equal to the parameter z. Therefore, the addition of PbTiO₃ which is effected in process step D) brings the elements Pb and Ti, which were previously added in a substoichiometric quantity, to a stoichiometric ratio which they will have in the finished ceramic material. Since the PbTiO₃ is only added after the calcining, it is retained for the subsequent sintering process and does not react with the PZT ceramic as early as during the calcining.

This has the advantage that the proportion a of PbTiO₃ is still present as such before the sintering step. The PbTiO₃ promotes the grain growth during the sintering process step.

The grain growth can thereby be controlled in a targeted manner by the addition of the PbTiO₃ to a selected, exactly determined proportion.

This has the advantage that, unlike in other sintering aids, no foreign ions are added which are then incorporated in the ceramic material and have a disadvantageous effect on the piezoelectric properties of the ceramic material. A further advantage is that the ceramic material does not have to be sintered at temperatures as high as those in the case where it is desirable to achieve a corresponding grain size for the ceramic material without the addition of the PbTiO₃ after the calcining. By way of example, the ceramic material of the composition

Pb_{1-(m/2)x-z+z}M^{m}ₓ (Zr_{1-y}Ti_{y-z+z})O₃+a-zPbTiO₃

can thus be sintered at a temperature of as low as 1070° C., whereas the corresponding ceramic material in which PbTiO₃ is not added after the calcining would require a sintering temperature of 1120° C. in order to achieve a corresponding grain growth.

The reduction in the sintering temperature has the further advantage that it is possible to use more favorable materials for, for example, inner electrodes which are sintered with the ceramic material. It is thereby possible, by way of example, to reduce the Pd proportion of a Pd—Ag alloy from 30% to 20%. However, the inner electrodes can also comprise a Cu alloy or include pure Cu.

The addition of the PbTiO₃ in process step D) is followed by renewed mixing and subsequent milling of the mixture in process step E). A stirred ball mill comprising zirconium oxide milling balls can again be used for the milling. Only this time, the ceramic particles are preferably milled to a size of about 0.5 μm.

In the subsequent sintering step, step F), the mixture is then sintered to give a ceramic material of the general formula: Pb_{1-(m/2)x-z+z}M^{m}ₓ(Zr_{1-y}Ti_{y-z+z})O₃+a-zPbTiO₃, where M is an element selected from: Nd, La, Ba, Sr, Sb, Bi, K, Na, and where: 0≦x≦0.1; 0.3≦y≦0.7; 0≦z≦y; 0≦(a-z) ≦0.03, and m, corresponding to the valency of the respective metal M, has the value +1, +2 or +3. The ceramic material thereby obtained has very good piezoelectric properties, without it having been necessary to heat the material to very high temperatures or without it having been necessary to add sintering aids which comprise foreign ions.

In a further variant of the process, shaped parts are formed between process steps E) and F) as a further process step E1). By way of example, this can involve the formation of green sheets which can be stacked to form a multilayered component, by way of example, in a further, additional process step before or after the sintering.

In order to form the green sheets, a binder can be added to the ceramic material, for example. A thermally degradable binder is advantageous here.

It is possible to use a low-melting metal, such as for example Cu, for the inner electrodes of the multilayered component. On account of the lowered sintering temperature, it is now possible to sinter multilayered components together with the inner electrodes thereof, even if the inner electrodes are produced from a low-melting metal.

The multilayered component can be sintered, for example, under an air atmosphere, but also under an N₂ atmosphere, to which H₂ is added and where the oxygen partial pressure is controlled by metering in water vapor. By controlling the oxygen partial pressure, it is possible, for example, to avoid the oxidation of the inner electrodes.

The binder in the green sheets can be removed in a further process step before the sintering step. To this end, it is likewise possible to use the two abovementioned atmospheres.

In a further variant of the process, the following holds true: a=z. A ceramic material of the general formula Pb_{1-(m/2)x-z+z}M^{m}ₓ (Zr_{1-y}Ti_{y-z+z})O₃ is therefore present after the sintering.

In this variant, in process step D) the stoichiometric proportion of the PbTiO₃ is chosen precisely such as to correspond to the quantity in which the elements Pb and Ti were used substoichiometrically in process step A). This means that the Pb and Ti ions added in process step D) can be incorporated completely at the lattice sites of the Pb_{1-(m/2)x-z+z}M^{m}ₓ (Zr_{1-y}Ti_{y-z+z})O₃. A single-phase, homogeneous ceramic material therefore results after the sintering step F). For the parameters lying in the ranges given in each case, this has very good piezoelectric properties.

The mean grain size of the finished ceramic material is increased by the addition of the PbTiO₃ in process step D).

Since, as already mentioned above, the grain growth or the grain size is directly linked to the piezoelectric properties of the ceramic material, in this process the grain size or the piezoelectric properties of the material are controlled by the addition of the PbTiO₃ in process step D). In conventional processes, the grain growth is generally controlled either by the addition of sintering aids containing foreign ions, or exclusively via the sintering temperature.

In a further variant of the process, the following holds true for the parameter z: 0.01≦z≦0.1.

In a further variant of the process, the following holds true for the parameters z and a: 0≦(a-z) <0.01.

Ceramic materials having particularly good piezoelectric properties could be achieved for the thus selected parameters.

In a further variant of the process, the starting substances are provided as oxides in process step A).

By way of example, the elements Zr and Ti are thus each introduced independently of one another as oxides ZrO₂ and TiO₂.

In a further variant of the process, the starting substances Zr and Ti are provided as precursors in the form of zirconium-titanium oxide (ZTO) or zirconium-titanium hydride (ZTH) in process step A).

By using the precursor, it is possible for the conversion during the calcining to be effected at lower temperatures. Furthermore, the formation of PbTiO₃ can be minimized or precluded. The quantity of PbTiO₃ present before the sintering step should as far as possible correspond exactly to the quantity added in process step D). It is therefore possible to promote the grain growth in a targeted manner.

In a further variant of the process, the mixture is calcined at a temperature of 850° C. to 950° C. in process step C).

In a further variant, in which the above-described precursor is used, the mixture is calcined at a temperature of 600° C. to 800° C. in process step C).

The calcining can be effected, for example, under an air atmosphere for a period of time of 10 to 20 hours. The holding time at the maximum temperature can be 4 hours in this case, for example.

In a further variant of the process, the mixture is sintered at a temperature of 900° C. to 1200° C. in process step F).

The sintering can be effected, for example, under an air atmosphere for a period of time of 24 hours. The holding time at the maximum temperature can be 4 hours in this case, for example.

A possible area of use for the piezoelectric ceramic material is explained hereinbelow on the basis of an exemplary embodiment of a component.

### DESCRIPTION OF THE DRAWING

FIG. 1 is a schematic side view showing a piezoelectric actuator.

### DETAILED DESCRIPTION

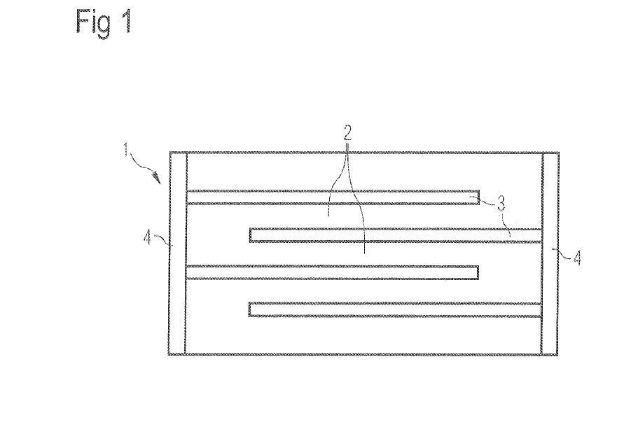

FIG. 1 is a schematic side view showing a possible embodiment, for a component, for which the ceramic material can be used. FIG. 1 is a schematic side view showing a piezoelectric actuator 1. In this case, the piezoelectric actuator 1 comprises ceramic layers 2, between which there are arranged inner electrodes 3. Here, the inner electrodes 3 are in each case electrically conductively connected to one of the two outer electrodes 4 in an alternating manner. In this case, the ceramic layers 2 comprise a ceramic material as has been described above. A piezoelectric actuator 1 as shown in the figure can be produced, for example, by a process in which ceramic green sheets are layered with inner electrodes in an alternating manner. By way of example, these green sheets can be formed in a preceding process step by adding a binder to the ceramic material. The layer stack comprising the inner electrodes 3 and the ceramic layers 2 can then be sintered in a common sintering process, for example. In this respect, it is advantageous to keep the sintering temperature as low as possible, since it is thereby possible to use a material for the inner electrodes 3 which has a lower melting point than the very expensive precious metals, such as for example Pd. By way of example, it is possible to use Cu in the form of an alloy or else pure Cu for the inner electrodes. As an alternative, however, it is also possible to use a Pd—Ag alloy having a composition of Pd/Ag to the proportions 20/80. After the layer stack has been sintered, it can further be provided with the outer electrodes 4 in a further process step. In this case, it is desirable that the ceramic material has very good piezoelectric properties in spite of the low sintering temperature, since the performance of the component depends on said properties.

The description on the basis of the exemplary embodiments does not limit the claims thereto. Instead, the claims encompasses any new feature and also any combination of features, which in particular contains any combination of features in the patent claims, even if this feature or this combination is itself not explicitly specified in the patent claims or exemplary embodiments.

What is claimed is:

1. A material comprising:
a ceramic material having a general formula of:
Pb_{1-(m/2)x-z+z}M^{m}ₓ (Zr_{1-y}Ti_{y-z+z})O₃+a-zPbTiO₃,
where M is at least one element selected from: Nd, La, Ba, Sr, Sb, Bi, K, Na;
where: 0≦x≦0.1, 0.3≦y≦0.7, 0≦z≦y; 0≦(a-z) ≦0.03; and
where m corresponds to a valency of a metal M, and where m has a value +1, +2 or +3.

2. The ceramic material according to claim 1, where: 0.02≦x≦0.03.

3. The ceramic material of claim 1 or 2, wherein a mean grain size of the ceramic material is in a range of 1 μm to 3 μm.

4. The ceramic material of claim 1 or 2, wherein the ceramic material has a density in the range of 7.6 to 8.1 g/cm³.

5. The ceramic material of claim 1 or 2, wherein the ceramic material comprises no additional sintering aids.

6. A method of producing a ceramic material comprising the following operations:
A) providing starting substances comprising Pb to a stoichiometric proportion of 1-x-z, M to a stoichiometric proportion of x, Zr to a stoichiometric proportion of 1-y and Ti to a stoichiometric proportion of y-z;
B) mixing and pre-milling the starting substances to produce a first mixture;
C) calcining the first mixture;
D) adding PbTiO₃ to the first mixture to a stoichiometric proportion of a to produce a second mixture;
E) mixing and subsequently milling the second mixture to produce a third mixture;
F) sintering the third mixture to produce a ceramic material of the general formula:
Pb_{1-(m/2)x-z+z}M^{m}ₓ (Zr_{1-y}Ti_{y-z+z})O₃,
where M is an element selected from: Nd, La, Ba, Sr, Sb, Bi, K, Na, where: 0≦x≦0.1; 0.3≦y≦0.7; 0≦z≦y; 0≦(a-z) ≦0.03, and where m corresponds to the valency of a metal M and has a value +1, +2 or +3.

7. The method of to claim 6, further comprising, between operations E) and F), forming shaped parts.

8. The method of claim 6 or 7, where a=z, such that a ceramic material of the following general formula is present following sintering:
Pb_{1-(m/2)x-z+z}M^{m}ₓ (Zr_{1-y}Ti_{y-z+z})O₃.

9. The method of claim 6 or 7, further comprising adding PbTiO₃ in operation D), thereby increasing a mean grain size of the ceramic material.

10. The method of claim 6 or 7, where 0.01≦z≦0.1.

11. The method of claim 6 or 7, where 0≦(a-z) <0.01.

12. The method of claim 6 or 7, wherein the starting substances are provided as oxides.

13. The method according to one of claim 6 or 7, wherein the starting substances Zr and Ti are provided as precursors comprising zirconium-titanium oxide (ZTO) or zirconium-titanium hydride (ZTH.

14. The method according to one of claim 6 or 7, wherein the first mixture is calcined at a temperature of 600° C. to 950° C.

15. The method according to one of claim 6 or 7, wherein the third mixture is sintered at a temperature of 900° C. to 1200° C.
